(19) United States
(12) Patent Application Publication
(10) Pub. No.: US 2026/0190352 A1
(43) Pub. Date: Jul. 2, 2026

(54) METHOD OF FORMING CHALCOGENIDE-BASED THIN FILM BY ATOMIC LAYER DEPOSITION AND METHOD OF FABRICATING MEMORY DEVICE USING THE CHALCOGENIDE-BASED THIN FILM

(71) Applicants: Samsung Electronics Co., Ltd., Suwon-si (KR); UIF (University Industry Foundation), Yonsei University, Seoul (KR)

(72) Inventors: Wooyoung YANG, Suwon-si (KR); Hyungjun KIM, Seoul (KR); Youngjae KANG, Suwon-si (KR); Jongbong PARK, Suwon-si (KR); Kiyeon YANG, Suwon-si (KR); Jeongwoo SEO, Suwon-si (KR); Inkyu SOHN, Suwon-si (KR); Minu CHO, Suwon-si (KR)

(73) Assignees: Samsung Electronics Co., Ltd., Suwon-si (KR); UIF (University Industry Foundation), Yonsei University, Seoul (KR)

(21) Appl. No.: 19/433,362

(22) Filed: Dec. 26, 2025

(30) Foreign Application Priority Data
Dec. 31, 2024 (KR) 10-2024-0202515

(51) Int. Cl. H10B 63/00

(52) U.S. Cl. CPC H10B 63/24

(57) ABSTRACT

A method of forming a chalcogenide-based thin film by atomic layer deposition may include a first cycle of forming a Ge—Se layer on a substrate by supplying a Ge precursor, a Se precursor, and a C₁-C₄ alcohol as a co-reactant into a reaction chamber provided with the substrate, and a second cycle of forming a Sb—Se layer on the substrate by supplying a Sb precursor, a Se precursor, and a C₁-C₃ alcohol, as a co-reactant into the reaction chamber. The Ge precursor may include an alkylamine group. The Se precursor may include an alkylsilyl group. The Sb precursor may include an alkoxide group. The first cycle may include p first subcycles. The second cycle may include q second subcycles. Also, p and q are each independently may be selected from integers of 1 to 10. The first cycle and the second cycle may be alternately performed multiple times.

### CROSS-REFERENCE TO RELATED APPLICATION

This application is based on and claims priority under 35 U.S.C. § 119 to Korean Patent Application No. 10-2024-0202515, filed on Dec. 31, 2024, in the Korean Intellectual Property Office, the disclosure of which is incorporated by reference herein in its entirety.

### BACKGROUND

### 1. Field

The disclosure relates to a method of forming a chalcogenide-based thin film by atomic layer deposition and/or a method of fabricating a memory device using the chalcogenide-based thin film.

### 2. Description of the Related Art

In the semiconductor industry, the development of next-generation memory devices is on the rise to improve the degree of integration and to dramatically improve performance of devices. Among next-generation memory device technologies, storage class memory (SCM) having combined functions of DRAM and storage has drawn attention. Selector only memory (SOM), one of the representative SCMs, is based on an Ovonic threshold switching (OTS) material and stores information based on a difference in threshold voltage Vₜₕ controllable by an electrical pulse. The SOM device is highly evaluated for simple structure, very low power consumption, and nanosecond-level fast data processing speed. A vertical SOM device, as a SOM device having a three-dimensionally expanded structure, has a further increased degree of integration.

Although a chalcogenide-based material may be used as an OTS layer of a SOM due to an appropriate level of threshold voltage (Vₜₕ) and a low off current (I_{off}), there may be a limit to deposit a uniform thin film in a vertical SOM device in the case of applying physical vapor deposition (PVD) thereto.

### SUMMARY

Provided is a method of forming a chalcogenide-based thin film by atomic layer deposition having an improved step coverage property and/or a more uniform composition.

Provided is a method of fabricating a memory device in which the chalcogenide-based thin film is applied to an Ovonic threshold switching (OTS) material layer.

Additional aspects will be set forth in part in the description which follows and, in part, will be apparent from the description, or may be learned by practice of the presented embodiments of the disclosure.

According to an embodiment, a method of forming a chalcogenide-based thin film by atomic layer deposition may include
a first cycle of forming a Ge—Se layer on a substrate, the first cycle including supplying a Ge precursor, a Se precursor, and a C₁-C₄ alcohol as co-reactants into a reaction chamber while the substrate is in the reaction chamber; and
a second cycle of forming a Sb—Se layer on the substrate, the second cycle including supplying a Sb precursor, the Se precursor, and a C₁-C₃ alcohol as co-reactants into the reaction chamber while the substrate is in the reaction chamber, wherein
the Ge precursor may include an amine ligand,
the Se precursor may include an alkylsilyl group,
the Sb precursor may include an alkoxide group,
the first cycle may include p first subcycles,
the second cycle may include q second subcycles,
among the p first subcycles and the q second subcycles, p and q each independently may be selected from integers of 1 to 10, and
the first cycle and the second cycle may be alternately performed multiple times.

According to an embodiment of the disclosure, a method of forming a chalcogenide-based thin film by atomic layer deposition may include
repeating a cycle of forming a Sb—Se layer on a substrate by supplying a Sb precursor, a Se precursor, and a C₁-C₃ alcohol as a co-reactant to a reaction chamber while the substrate is in the reaction chamber,
wherein the Sb precursor may include an alkoxide group, and the Se precursor may include an alkylsilyl group.

According to an embodiment of the disclosure, a method of fabricating a memory device may include
forming a stack structure including conductive layers and insulating layers alternately stacked on a substrate,
forming a through-hole in the stack structure, the through-hole vertically extending through the stack structure,
forming a chalcogenide layer on a side wall of the through-hole, and
filling the through-hole with a conductive material after the forming the chalcogenide layer on the side wall of the through-hole,
wherein the forming the chalcogenide layer on the side wall of the through-hole may include:
inserting the substrate having the through-hole, the through-hole being defined by the stack structure on the substrate, into the reaction chamber,
a first cycle of forming a Ge—Se layer on the side wall of the through-hole by supplying a Ge precursor, a Se precursor, and a C₁-C₄ alcohol to the reaction chamber, and
a second cycle of forming a Sb—Se layer on the side wall of the through-hole by supplying a Sb precursor, the Se precursor, and a C₁-C₃ alcohol to the reaction chamber,
wherein the Ge precursor may include an alkylamine group, the Se precursor may include an alkylsilyl group, and the Sb precursor may include an alkoxide group,
the first cycle may include p first subcycles,
the second cycle may include q second subcycles,
among the p first subcycles and the q second subcycles, the p and the q each may be independently selected from integers of 1 to 10, and
the first cycle and the second cycle may be alternately performed multiple times.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram for describing a method of forming a chalcogenide-based thin film by atomic layer deposition according to an embodiment;

FIG. 2 is a diagram for describing a method of forming a chalcogenide-based thin film by atomic layer deposition according to another embodiment;

FIGS. 3A to 3D are schematic cross-sectional views for sequentially describing a method of fabricating a memory device according to an embodiment;

FIG. 4 is a schematic perspective view of a memory device according to an embodiment;

FIG. 5 is a schematic horizontal cross-sectional view of a memory cell in the memory device illustrated in FIG. 4;

FIG. 6 is a schematic vertical cross-sectional view of a memory cell string of the memory device illustrated in FIG. 4;

FIG. 7 is a graph of an example showing voltage-current characteristics of an Ovonic threshold switching material layer of a memory device;

FIG. 8A is a graph of an example showing bias voltages for set operation SET and reading operation in a memory device according to an embodiment;

FIG. 8B is a graph of an example showing bias voltages for reset operation RESET and reading operation in a memory device according to an embodiment;

FIG. 9 is a graph of an example showing a composition ratio of elements constituting an Ovonic threshold switching material layer;

FIG. 10 is a conceptual diagram schematically illustrating a device architecture applicable to electronic devices according to an embodiment;

FIGS. 11 and 12 are graphs showing thicknesses of Sb—Se thin films formed according to Example 1 and Comparative Example 1, respectively, with respect to the number of ALD cycles;

FIG. 13 shows AFM images of Sb—Se thin films formed by performing ALD cycles 56 times and 112 times according to a method of Example 1;

FIG. 14 shows AFM images of Sb—Se thin films formed by performing ALD cycles 50 times and 100 times, respectively according to a method of Comparative Example 1;

FIG. 15 is a cross-sectional SEM image of a Sb—Se thin film formed according to a method of Example 1;

FIG. 16 is a graph of showing atomic % of Ge, Sb and Se in Ge—Sb—Se thin films of Examples 2 to 4 according to a ratio of the number (p) of Ge—Se subcycles to the number (q) of Sb—Se subcycles (p:q); and

FIG. 17 shows cross-sectional TEM images of a structure of Example 5.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the term “equal to” is used in the description of example embodiments, it should be understood that some imprecisions may exist. Thus, when one element is referred to as “equal to” another element, it should be understood that an element or a value may be “equal to” another element within a desired manufacturing or operational tolerance range (e.g., ±10%).

The notion that elements are “substantially the same” may indicate that the element may be completely the same and may also indicate that the elements may be determined to be the same in consideration of errors or deviations occurring during a process.

Hereinafter, a method of forming a chalcogenide-based thin film by atomic layer deposition and a method of fabricating a memory device using the chalcogenide-based thin film will be described in detail with reference to the accompanying drawings. In the drawings, like reference numerals in the drawings denote like elements, and elements may be exaggerated for clarity and convenience of description. In addition, it should be understood that embodiments described hereinafter are merely for illustrative purposes, various changes in form from the embodiments may be made.

Hereinafter, an element referred to as being “above/below” or “on/under” another element may be directly on/under the other element in contact therewith or intervening elements may also be present. An expression used in the singular encompasses the expression of the plural, unless it has a clearly different meaning in the context. In addition, the term “include” is intended to indicate that an element do not preclude the other elements but further add and/or intervene another element, unless otherwise stated.

The term “the” and similar terms may refer to both singular and plural forms. The reference numerals used in operations are not intended to describe the order of operations and the operations may be performed in a different order unless otherwise stated. The disclosure is not limited by the order of operations.

Connection lines or connection members between the components illustrated in the drawings are merely illustrative of functional connections and/or physical or circuit connections. In actual devices, connections between the components may be represented by various functional connections, physical connections, or circuit connections that may be replaced or added.

All examples and example terms are used to simply describe the technical conception in detail, and the scope of the disclosure is not limited by these examples and example terms unless limited by the following claims.

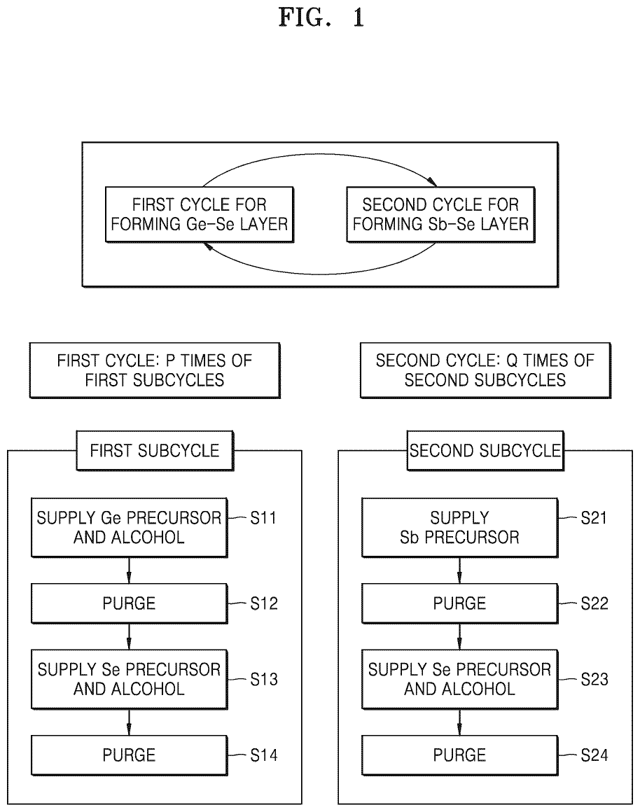

FIG. 1 is a diagram for describing a method of forming a chalcogenide-based thin film by atomic layer deposition according to an embodiment. Referring to FIG. 1, according to the method of forming a chalcogenide-based thin film by atomic layer deposition according to an embodiment, a Ge—Sb—Se layer is formed by alternately repeating a first cycle for forming a Ge—Se layer and a second cycle for forming a Sb—Se layer.

As used herein, the Ge—Se layer refers to a layer formed of a compound of germanium (Ge) and selenium (Se). The compound of germanium (Ge) and selenium (Se) may be a GeₓSe₁₋ₓ compound (where 0.2<x<0.7). Meanwhile, the Ge—Se layer may be formed of one atomic layer to several tens of atomic layers.

As used herein, the Sb—Se layer refers to a layer formed of a compound of antimony (Sb) and selenium (Se). The compound of antimony (Sb) and selenium (Se) may be a Sb_{y}Se_{1-y} (where 0.2<y<0.6) compound. Meanwhile, the Sb—Se layer may be formed of one atomic layer to several tens of atomic layers.

In the atomic layer deposition process, the Ge—Se layer and the Sb—Se layer alternately formed may react with each other to form the Ge—Sb—Se layer (or thin film).

Throughout the specification, the Ge—Sb—Se layer refers to a layer formed of a compound of germanium (Ge), antimony (Sb), and selenium (Se). The compound of germanium (Ge), antimony (Sb), and selenium (Se) may be a compound including about 10 at % to about 40 at % of germanium (Ge), about 10 at % to about 40 at % of antimony (Sb), and about 30 at % to about 60 at % of selenium (Se). In the method of forming a chalcogenide-based thin film by atomic layer deposition, a thickness of the final Ge—Sb—Se layer (or thin film) may be from about 10 nm to about 30 nm.

The first cycle for forming the Ge—Se layer includes supplying a Ge precursor, Se precursor, and a first alcohol (e.g., a C₁-C₄ alcohol) as a co-reactant into a reaction chamber provided with a substrate, and the second cycle for forming the Sb—Se layer includes supplying a Sb precursor, a Se precursor, and a second alcohol (e.g., C₁-C₄ alcohol) as a co-reactant into a reaction chamber provided with the substrate. The first alcohol and the second alcohol may be the same or different.

The substrate may include various materials, and various material layers such as an insulator layer, a conductor layer, and a semiconductor layer may be formed on the substrate. The substrate may include, for example, silicon, silicon oxide, and titanium nitride. The insulator layer may include, for example, a silicon oxide layer and a silicon nitride layer. The conductor layer may include, for example, a metal compound layer such as TiN and a metal layer. Meanwhile, the substrate may refer to a state on which the Ge—Se layer and/or the Sb—Se layer are formed by the first cycle and/or the second cycle on the substrate.

The first cycle may include performing a first subcycle once or more. For example, the first cycle may be performed by conducting the first subcycle p times, where p may be an integer from 1 to 10.

In the first cycle, the Ge precursor, the Se precursor, and the first alcohol (e.g., C₁-C₄ alcohol) as a co-reactant may be added to the reaction chamber in accordance with a preset order in the first subcycle. Referring to FIG. 1, the first subcycle may include: supplying the Ge precursor and the first alcohol into the reaction chamber provided with the substrate (S11); purging the reaction chamber (S12); supplying the Se precursor and the first alcohol into the reaction chamber (S13); and purging the reaction chamber (S14). In an embodiment, the first cycle may be performed at a temperature of about 50° C. to about 150° C.

In S11, the Ge precursor may react with the first alcohol to produce an intermediate product of a Ge (II) alkoxide. In an embodiment, the Ge precursor may be a germylene compound including an amide ligand. For example, the Ge precursor may be a compound represented by Ge(NR₂)₂ or Ge(N(SiR₃)₂)₂ (where R is each independently a C₁-C₄). For example, R may be a methyl group, an ethyl group, a n-propyl group, an iso-propyl group, a n-butyl group, a sec-butyl group, a tert-butyl group, and an iso-butyl group. For example, the Ge precursor may be Ge(N(SiMe₃)₂)₂ and Ge(NMe₂)₂, but the embodiment is not limited thereto. In an embodiment, the first alcohol may be a C₁-C₄ alcohol. Specifically, the first alcohol (and/or second alcohol) may be methanol, ethanol, n-propanol, iso-propanol, n-butanol, iso-butanol, sec-butanol or tert-butanol. For example, the first alcohol and/or the second alcohol may be methanol.

In S12, the purging of the reaction chamber may be performed by using an inert gas such as argon (Ar) or nitrogen (N₂), and the unreacted Ge precursor and the first alcohol may be removed from the reaction chamber.

In S13, the Se precursor may react with the first alcohol to produce a H₂Se (hydrogen selenide) compound. In an embodiment, the Se precursor may be a Se compound including an alkylsilyl group. For example, the Se precursor may be Se(SiMe₃)₂ or Se(SiEt₃)₂, but is not limited thereto. The H₂Se compound may inhibit the growth of islands and induce uniform nucleation during formation of the Ge—Se layer, thereby allowing uniform formation of the Ge—Se layer.

In S14, the purging of the reaction chamber may be performed by using an inert gas such as argon (Ar) or nitrogen (N₂) as described in S12, and the unreacted Se precursor and the first alcohol may be removed from the reaction chamber.

The second cycle may include performing a second subcycle once or more. For example, the second cycle may be performed by conducting the second subcycle q times, where q may be an integer from 1 to 10.

In the second cycle, the Sb precursor, the Se precursor, and the second alcohol (e.g., C₁-C₄ alcohol) as a co-reactant may be added to the reaction chamber in accordance with a preset order of the second subcycle. In an embodiment, the second subcycle may include: supplying the Sb precursor into the reaction chamber provided with the substrate (S21); purging the reaction chamber (S22); supplying the Se precursor and the second alcohol into the reaction chamber (S23); and purging the reaction chamber (S24). In an embodiment, the second cycle may be performed at a chamber temperature of about 50° C. to about 150° C.

In S21, the Sb precursor may be a Sb compound including an alkoxide group. For example, the Sb precursor may be Sb(OEt)₃, Sb(OEt)₃, ClSb(OEt)₂, or Cl₂SbOEt, but is not limited thereto. The Sb precursor supplied into the reaction chamber may react with hydrogen on the surface of the substrate to produce byproducts in the form of alcohol or HCl and may bind to Se on the surface of the substrate generated during the cycle process.

The purging of the reaction chamber of S22 refers to the above-described purging of the reaction chamber of S12.

In S23, the Se precursor may react with the second alcohol to produce a H₂Se (hydrogen selenide) compound. In an embodiment, the Se precursor may be a Se compound including an alkylsilyl group. For example, the Se precursor may be Se(SiMe₃)₂ or Se(SiEt₃)₂, but is not limited thereto. The H₂Se compound may inhibit the growth of islands and induce uniform nucleation during formation of the Sb—Se layer, thereby allowing uniform formation of the Sb—Se layer.

The purging of the reaction chamber of S24 refers to the above-described purging of the reaction chamber of S14.

In an embodiment, the Ge precursor, the Se precursor, the Sb precursor, and the second alcohol may be supplied to the reaction chamber by a carrier gas such as nitrogen or argon.

According to the method of forming a chalcogenide-based thin film by atomic layer deposition according to an embodiment, an atomic ratio of Ge, Sb and Se may be adjusted in the formed chalcogenide-based thin film by controlling a ratio of the number (p) of the first subcycles constituting the first cycle and the number (q) of the second subcycles constituting the second cycle. For example, the p:q ratio may be from about 1:1 to about 1:3. The chalcogenide-based thin film may be formed of a compound of germanium (Ge), antimony (Sb), and selenium (Se) and may include about 10 at % to about 40 at % of germanium (Ge), about 10 at % to about 40 at % of antimony (Sb), and about 30 at % to about 60 at % of selenium (Se).

In an embodiment, the first cycle for forming the Ge—Se layer may be started before the second cycle for forming the Sb—Se layer. In another embodiment, the second cycle for forming the Sb—Se layer may be started before the first cycle for forming the Ge—Se layer.

In addition, according to the method of forming a chalcogenide-based thin film by atomic layer deposition according to an embodiment, by forming the H₂Se intermediate product using the first alcohol as a co-reactant in the first subcycle and the second alcohol as a co-reactant in the second subcycle, where the first alcohol and the second alcohol may be same or different (e.g., C₁-C₄ alcohol), reactivity between the precursors for forming the Ge—Se layer and the Sb—Se layer may be increased and nucleation density may be increased so that the growth of islands of the thin film is inhibited and a uniform thin film with high step coverage property may be formed. In addition, components are more uniformly distributed in the chalcogenide-based thin film so as to obtain more uniformity of the composition. Accordingly, the chalcogenide-based thin film formed by atomic layer deposition according to an embodiment has reduced surface roughness. The chalcogenide-based thin film may have a surface roughness of, for example, about 0.3 nm (RMS) to about 1.5 nm (RMS).

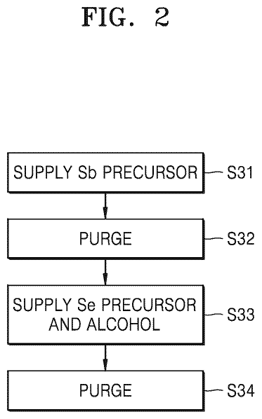

FIG. 2 is a diagram for describing a method of forming a chalcogenide-based thin film by atomic layer deposition according to another embodiment. Referring to FIG. 2, the method of forming a chalcogenide-based thin film by atomic layer deposition according to an embodiment may include: supplying a Sb precursor into a reaction chamber provided with a substrate (S31); purging the reaction chamber (S32); supplying a Se precursor and an alcohol (e.g., C₁-C₄ alcohol) into the reaction chamber (S33); and purging the reaction chamber (S34). In an embodiment, the method may be performed at a chamber temperature of about 50° C. to about 150° C.

In S31, the Sb precursor may be a Sb compound including an alkoxide group. For example, the Sb precursor may be Sb(OEt)₃, ClSb(OEt)₃, or Cl₂SbOEt, but is not limited thereto. The Sb precursor supplied to the reaction chamber may react with hydrogen on the surface of the substrate to produce byproducts in the form of alcohol or HCl and may bind to Se on the surface of the substrate generated during the cycle process.

The purging of the reaction chamber of S32 refers to the above-described purging of the reaction chamber of S12.

In S33, the Se precursor may react with the alcohol to produce a H₂Se (hydrogen selenide) compound. In an embodiment, the Se precursor may be a Se compound including an alkylsilyl group. For example, the Se precursor may be Se(SiMe₃)₂ or Se(SiEt₃)₂, but is not limited thereto. The H₂Se compound may inhibit the growth of islands and induce uniform nucleation during formation of the Sb—Se layer, thereby allowing uniform formation of the Sb—Se layer.

The purging of the reaction chamber of S34 refers to the above-described purging of the reaction chamber of S14.

In an embodiment, the Sb precursor, the Se precursor, and the alcohol may be supplied to the reaction chamber by a carrier gas such as nitrogen or argon.

The chalcogenide-based thin film formed by atomic layer deposition may be a Sb—Se thin film. The Sb—Se thin film may include a compound of antimony (Sb) and selenium (Se), and may be, for example, a compound represented by Sb₂Se₃.

According to the method of forming a chalcogenide-based thin film by atomic layer deposition according to an embodiment, by forming the H₂Se intermediate product using the alcohol as a co-reactant, reactivity between the precursors may be increased and nucleation density may be increased so that the growth of islands of the thin film may be inhibited and a more uniform thin film with higher step coverage property may be formed. In addition, components may be more uniformly distributed in the chalcogenide-based thin film so as to obtain improved uniformity of the composition.

The above-described chalcogenide-based thin film formed by atomic layer deposition has properties of an Ovonic threshold switching material and may be applied to electronic devices.

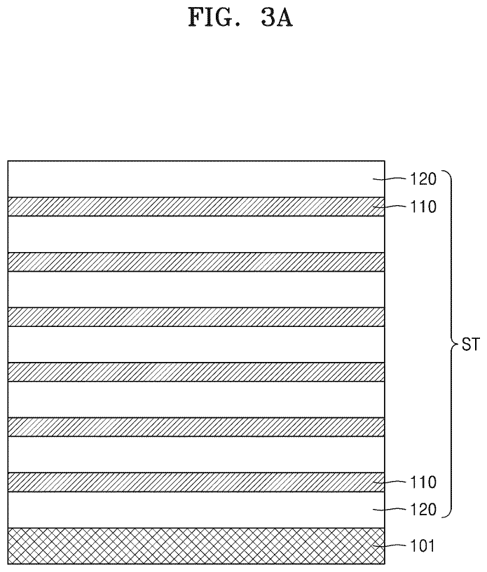

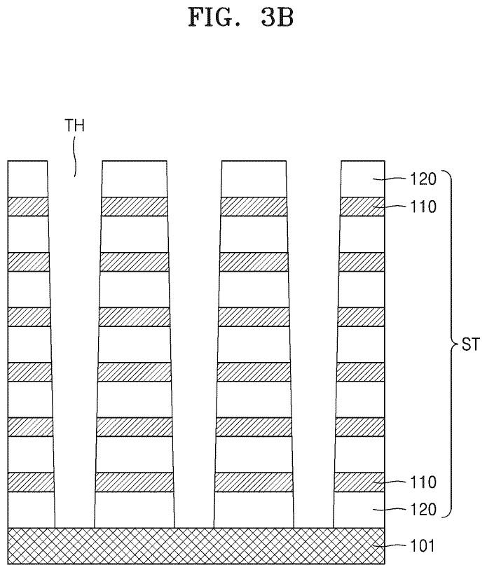

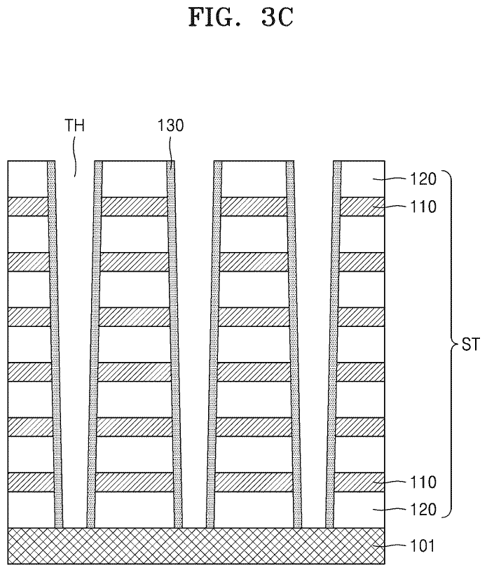

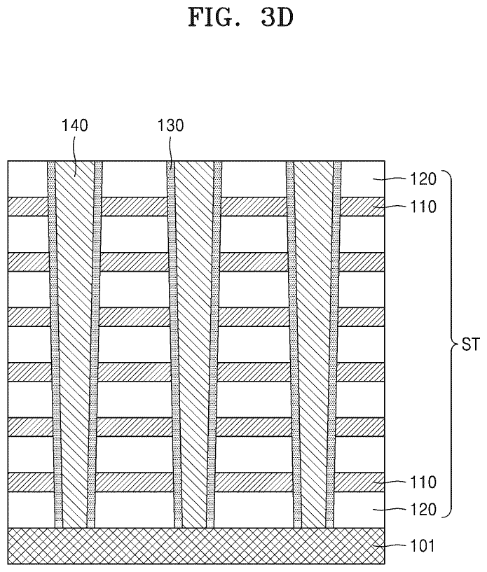

FIGS. 3A to 3D are schematic cross-sectional views for sequentially describing a method of fabricating a memory device according to an embodiment.

Referring to FIG. 3A, a conductive layer 110 and an insulating layer 120 are alternately stacked on a substrate 101 to form a stack structure ST.

The substrate 101 may include, for example, a silicon substrate, a germanium substrate, a silicon germanium substrate, an insulator substrate, a silicon on insulator (SOI) substrate, and a germanium on insulator (GOI) substrate, but is not limited thereto.

The conductive layer 110 may include, for example, titanium nitride, tungsten, and carbon, but is not limited thereto. The conductive layer 110 may be formed by, for example, chemical vapor deposition (CVD) or physical vapor deposition. In an embodiment, a thickness of the conductive layer 110 may be in a range of about 5 nm to about 30 nm. The conductive layer 110 may constitute a word plane WP of a memory device.

The insulating layer 120 may include, for example, an insulating dielectric material such as SiO₂, SiN, Al₂O₃, and HfO₂. The insulating layer 120 may be formed by, for example, chemical vapor deposition. In an embodiment, a thickness of the insulating layer 120 may be in a range of about 5 nm to about 30 nm. In an embodiment, the numbers of the conductive layer 110 and the insulating layer 120 may vary in various manners. In an embodiment, a height of the stack structure ST may include a range of about 50 nm to about 1000 nm, but is not limited thereto. The insulating layer 120 may constitute a dielectric layer of the memory device.

Referring to FIG. 3B, a through-hole TH vertically penetrating the stack structure ST may be formed. The through-hole TH may extend to the substrate 101 after penetrating the stack structure ST. In an embodiment, a diameter of the through-hole TH may include a range of about 5 nm to about 100 nm, but is not limited thereto.

Referring to FIG. 3C, a chalcogenide-based thin film 130, as an Ovonic threshold switching material, is formed on the side wall of the through-hole TH by using the method of forming a chalcogenide-based thin film by atomic layer deposition according to above-described embodiment. In an embodiment, the chalcogenide-based thin film 130 may be a Ge—Sb—Se thin film. The chalcogenide-based thin film 130 may be formed to a uniform thickness of about 5 nm to about 40 nm. The chalcogenide-based thin film 130 formed on the top surface of the stack structure ST and on the bottom of the through-hole TH may be removed. The chalcogenide-based thin film 130 may constitute an Ovonic threshold switching material layer OTS.

Referring to FIG. 3D, the through-hole TH formed with the chalcogenide-based thin film 130 is filled with a vertical conductive layer 140. In an embodiment, the vertical conductive layer 140 may be formed by depositing a conductive material to fill the through-hole TH and removing the conductive material formed on the top surface of the stack structure ST by chemical mechanical polishing (CMP) or the like. The conductive material may be, for example, titanium nitride, tungsten, and carbon, but is not limited thereto. The vertical conductive layer 140 may constitute a vertical bit line VBL.

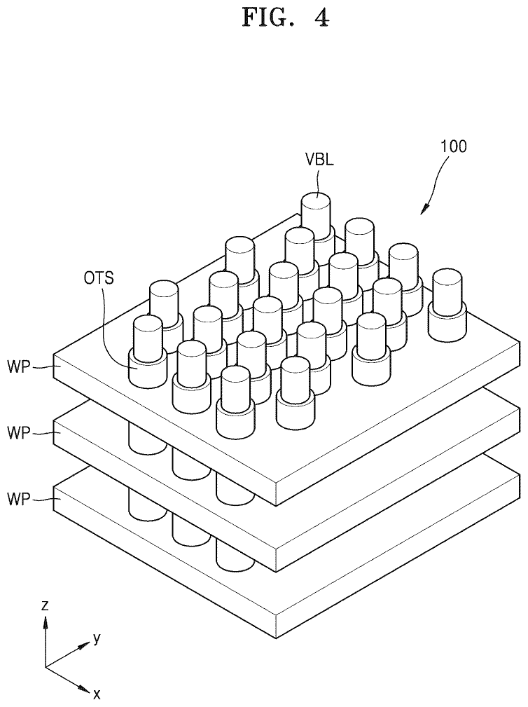

FIG. 4 is a schematic perspective view of a memory device according to an embodiment. Referring to FIG. 4, a memory device 100 according to an embodiment may include a plurality of word planes WPs extending along a plane including a first direction (i.e., X-axial direction) and a second direction (i.e., Y-axial direction) and arranged in a third direction (i.e., X-axial direction) perpendicular to the first direction and the second direction to be spaced apart from each other, a plurality of vertical bit lines VBLs extending in the third direction and two-dimensionally arranged along the first direction and the second direction, and a plurality of Ovonic threshold switching material layers OTSs extending in the third direction while surrounding the surface of each of the plurality of vertical bit lines VBLs. The plurality of Ovonic threshold switching material layers OTSs may also be two-dimensionally arranged along the first direction and the second direction like the plurality of vertical bit lines VBLs.

The plurality of Ovonic threshold switching material layers OTSs and the plurality of vertical bit lines VBLs may be arranged to pass through the plurality of word planes WPs in the third direction, respectively. Because the plurality of Ovonic threshold switching material layers OTSs and the plurality of vertical bit lines VBLs extend vertically, the memory device 100 shown in FIG. 4 may be referred to as a vertical memory device and may have a relatively high degree of integration and an increased memory capacity.

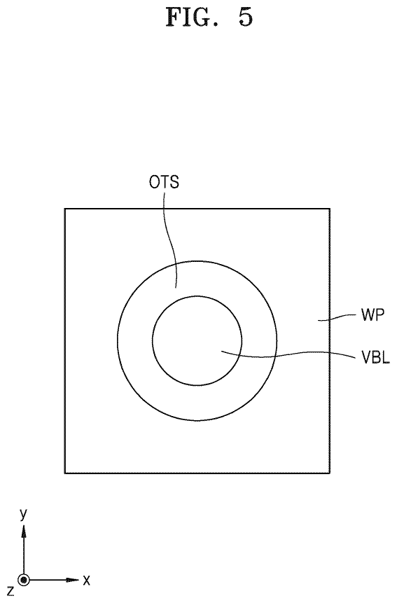

FIG. 5 is a schematic horizontal cross-sectional view of a memory cell in the memory device 100 illustrated in FIG. 4. Referring to FIG. 5, the vertical bit line VB may have, for example, a cylindrical shape. In addition, the Ovonic threshold switching material layer OTS may have a cylindrical shape surrounding the vertical bit line VBL. In the horizontal cross-sectional view, the Ovonic threshold switching material layer OTS may have a ring shape. The outer surface of the Ovonic threshold switching material layer OTS may be surrounded by the word plane WP.

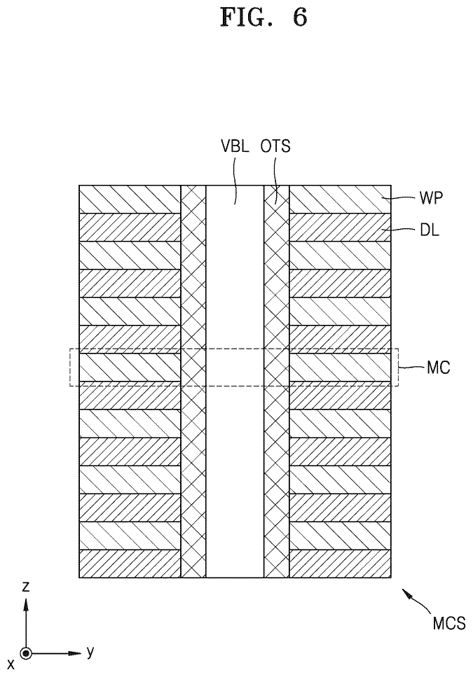

FIG. 6 is a schematic vertical cross-sectional view of a memory cell string of the memory device 100 illustrated in FIG. 4. Referring to FIG. 6, a memory cell string MCS extending in the third direction may include the vertical bit line VBL extending in the third direction, the Ovonic threshold switching material layer OTS surrounding the vertical bit line VBL and extending in the third direction, a plurality of word planes WPs arranged in the third direction to be spaced apart from each other while surrounding the external surface of the Ovonic threshold switching material layer OTS, and dielectric material layers DLs disposed between two adjacent word planes WPs in the third direction while surrounding the external surface of the Ovonic threshold switching material layer OTS. The dielectric material layer DL may be a spacer to maintain the interval between the two word planes WPs.

In one plane including the first and second directions (i.e., XY plane), a part of the Ovonic threshold switching material layer OTS and a part of the vertical bit line VBL surrounded by one word plane WP may form one memory cell MC together with the word plane WP corresponding thereto. Therefore, one memory cell string MCS may include a plurality of memory cells MCs arranged in the third direction to be spaced apart from each other. The memory device 100 may include a plurality of memory cell strings MCSs two-dimensionally arranged in the first and second directions. Based thereon, the plurality of memory cells MCs may be regarded as being arranged three-dimensionally in the first, second, and third directions. Each word plane WP may simultaneously supply a driving voltage and a reading voltage to the plurality of memory cells MCs two-dimensionally arranged on the same plane. The word plane WP and the vertical bit line VBL may include a conductive material. The dielectric material layer DL may include, for example, an insulating dielectric material such as SiO₂, SiN, Al₂O₃, and HfO₂.

The Ovonic threshold switching material layer OTS may include a material having Ovonic threshold switching properties. Particularly, the Ovonic threshold switching material layer OTS may have characteristic of a memory in which the threshold voltage is shifted depending on the polarity and intensity of a bias voltage applied thereto. Therefore, the Ovonic threshold switching material layer OTS may have characteristics of a self-selecting memory capable of performing both memory and selector functions only using a single material. To this end, the Ovonic threshold switching material layer OTS may include a single material of multi-nary chalcogenide.

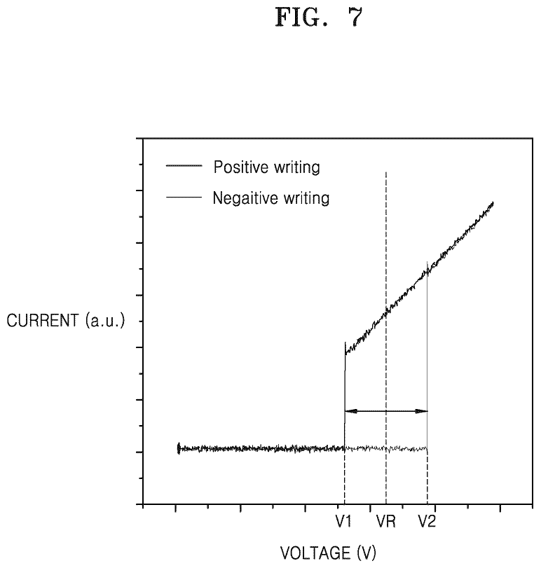

FIG. 7 is a graph of an example showing voltage-current characteristics of the Ovonic threshold switching material layer OTS of the memory device 100. Referring to FIG. 7, the Ovonic threshold switching material layer OTS may have a first state (low Vth state (LVS)) in which a threshold voltage is relatively low and a second state (high Vth state (HVS)) in which the threshold voltage is relatively high. For example, the threshold voltage of the Ovonic threshold switching material layer OTS in the first state may be a first voltage V1, and the threshold voltage of the Ovonic threshold switching material layer OTS in the second state may be a second voltage V2 higher than the first voltage V1. In the case where a voltage lower than the first voltage V1 is applied to the Ovonic threshold switching material layer OTS while the Ovonic threshold switching material layer OTS is in the first state, current hardly flows in the Ovonic threshold switching material layer OTS. In the case where a voltage higher than the first voltage V1 is applied to the Ovonic threshold switching material layer OTS, the Ovonic threshold switching material layer OTS is turned on to allow current to flow in the Ovonic threshold switching material layer OTS. Also, in the case where a voltage lower than the second voltage V2 is applied to the Ovonic threshold switching material layer OTS while the Ovonic threshold switching material layer OTS is in the second state, current hardly flows in the Ovonic threshold switching material layer OTS. In the case where a voltage higher than the second voltage V2 is applied to the Ovonic threshold switching material layer OTS, the Ovonic threshold switching material layer OTS is turned on to allow current to flow in the Ovonic threshold switching material layer OTS.

Therefore, a voltage between the first voltage V1 and the second voltage V2 may be selected as a reading voltage VR. In the case where the reading voltage VR is applied to the Ovonic threshold switching material layer OTS while the Ovonic threshold switching material layer OTS is in the first state, current flows through the Ovonic threshold switching material layer OTS, and a data value stored in the Ovonic threshold switching material layer OTS in this case may be defined as “1”. In the case where the reading voltage VR is applied to the Ovonic threshold switching material layer OTS while the Ovonic threshold switching material layer OTS is in the second state, current hardly flows through the Ovonic threshold switching material layer OTS, and a data value stored in the Ovonic threshold switching material layer OTS in this case may be defined as “0”. In other words, the data value stored in the Ovonic threshold switching material layer OTS may be read by measuring the current flowing in the Ovonic threshold switching material layer OTS while the reading voltage VR is applied to the Ovonic threshold switching material layer OTS.

Meanwhile, in the case where a negative (−) bias voltage is applied to the Ovonic threshold switching material layer OTS while the Ovonic threshold switching material layer OTS is in the first state, the threshold voltage of the Ovonic threshold switching material layer OTS increases so that the Ovonic threshold switching material layer OTS may be switched to the second state (negative writing). For example, upon application of a negative third voltage to the Ovonic threshold switching material layer OTS, the Ovonic threshold switching material layer OTS may be switched to the second state. This operation may be referred to as ‘RESET’ operation. In addition, in the case where a positive (+) bias voltage higher than the second voltage V2 is applied to the Ovonic threshold switching material layer OTS while the Ovonic threshold switching material layer OTS is in the second state, the threshold voltage of the Ovonic threshold switching material layer OTS decreases, so that the Ovonic threshold switching material layer OTS may be switched to the first state (positive writing). This operation may be referred to as ‘SET’ operation.

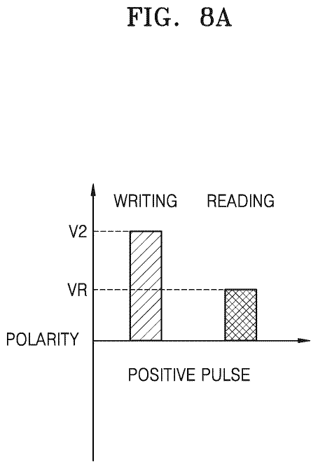

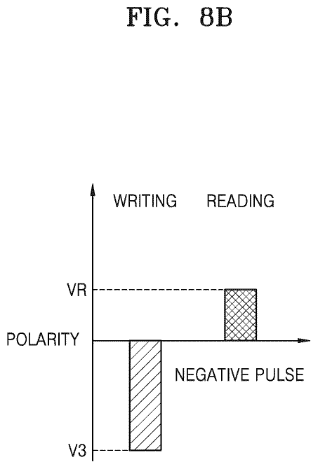

FIG. 8A is a graph of an example showing bias voltages for a set operation SET and a reading operation in the memory device 100 according to an embodiment. Referring to FIG. 8A, in the set operation SET, a positive bias voltage higher than the second voltage V2 may be applied to the Ovonic threshold switching material layer OTS. As a result, the threshold voltage of the Ovonic threshold switching material layer OTS may be shifted to the first voltage V1. Thereafter, in the reading operation, a positive reading voltage VR between the first voltage V1 and the second voltage V2 may be applied to the Ovonic threshold switching material layer OTS. Upon application of the reading voltage VR, the Ovonic threshold switching material layer OTS may be turned on.

FIG. 8B is a graph of an example showing bias voltages for a reset operation RESET and a reading operation in the memory device 100 according to an embodiment. Referring to FIG. 8B, in the reset operation RESET, a negative bias voltage, e.g., negative third voltage V3, may be applied to the Ovonic threshold switching material layer OTS. An absolute value of the third voltage V3 may be approximately equal to or slightly greater or smaller than that of the second voltage V2. As a result, the threshold voltage of the Ovonic threshold switching material layer OTS may be shifted to the second voltage higher than the first voltage V1. Thereafter, in the reading operation, a positive reading voltage VR between the first voltage V1 and the second voltage V2 may be applied to the Ovonic threshold switching material layer OTS. Upon application of the reading voltage VR, the Ovonic threshold switching material layer OTS may be turned off.

As described above, the Ovonic threshold switching material layer OTS of the memory device 100 according to an embodiment may have both Ovonic threshold switching characteristics and threshold voltage-changing characteristics of a memory. Particularly, the threshold voltage of the Ovonic threshold switching material layer OTS may be shifted according to the polarity of the bias voltage applied to the Ovonic threshold switching material layer OTS. Therefore, each of the memory cells MCs of the memory device 100 according to an embodiment does not need to include a selector layer and a memory layer, separately, and the switching operation and the memory operation may be performed by using only one single Ovonic threshold switching material layer OTS. Based thereon, the memory device 100 according to an embodiment may be a selector only memory (SOM). Particularly, because the plurality of memory cells MCs have a vertical structure arranged in the vertical direction, the memory device 100 may be a vertical SOM (VSOM).

According to an embodiment, an Ovonic threshold switching material of the Ovonic threshold switching material layer OTS having the above-described characteristics may be, for example, a single material of multi-nary chalcogenide including germanium (Ge), antimony (Sb), and selenium (Se). Particularly, the Ovonic threshold switching material layer OTS according to an embodiment may include Ge—Sb—Se.

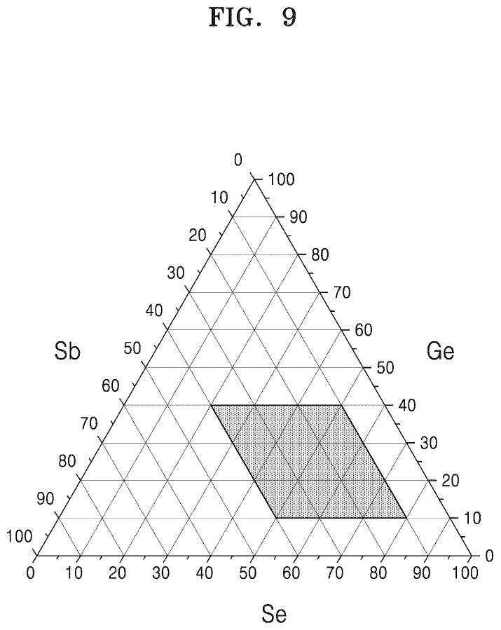

FIG. 9 is a graph of an example showing a composition ratio of elements constituting the Ovonic threshold switching material layer OTS according to an embodiment. Referring to FIG. 9, in the Ge—Sb—Se as a material of the Ovonic threshold switching material layer OTS, a ratio of germanium (Ge) may be, for example, at least about 10 at % but not more than about 40 at %, a ratio of antimony (Sb) may be, for example, at least about 10 at % but not more than about 40 at %, and a ratio of selenium (Se) may be, for example, at least about 20 at % but not more than about 80 at %. FIG. 9 shows a composition of germanium (Ge), antimony (Sb), and selenium (Se) among the materials of the Ovonic threshold switching material layer OTS.

To implement the memory device 100 illustrated in FIGS. 4 to 6, the chalcogenide-based thin film may be deposited by atomic layer deposition (ALD) according to embodiments on the side wall of each hole for forming the vertical bit line VBL, so that the Ovonic threshold switching material layer OTS may be more uniformly formed on the surface of the vertical bit line VBL.

Meanwhile, in the case where a voltage V is applied to the Ovonic threshold switching material layer OTS of a memory cell selected from the plurality of memory cells MCs three-dimensionally arranged in the memory device 100 shown in FIGS. 4 to 6 (hereinafter, referred to as “the selected memory cell”), the voltage V may be applied to the word plane WP of the selected memory cell and a half voltage V/2 may be applied to the other word planes WPs. In addition, 0 V may be applied to the vertical bit line VBL of the selected memory cell, and the V/2 voltage may be applied to the other vertical bit lines VBLs. Then, a potential difference between the word plane P of the selected memory cell and the vertical bit line VBL may be V. Meanwhile, a potential difference between the vertical bit line VBL to which the V/2 is applied and the vertical bit line VBL to which the V/2 is applied may be 0 V. Therefore, the voltage is not applied to a non-selected memory cell disposed between the word plane WP and the vertical bit line VBL, which are not connected to the selected memory cell. The V/2 voltage may be applied to an Ovonic threshold switching material layer OTS of a memory cell, which is connected to the same word plane WP as the word plane WP of the selected memory cell or connected to the same vertical bit line VBL as the vertical bit line VBL of the selected memory cells MC (hereinafter, referred to as “quasi-selected memory cell”). The Ovonic threshold switching material layer OTS according to an embodiment is a self-selecting device having the threshold voltage as described above. Therefore, although the V/2 voltage is applied to the Ovonic threshold switching material layer OTS of the quasi-selected memory cell adjacent to the selected memory cell, the Ovonic threshold switching material layer OTS of the quasi-selected memory cell is not turned on. As a result, leakage current may be negligible.

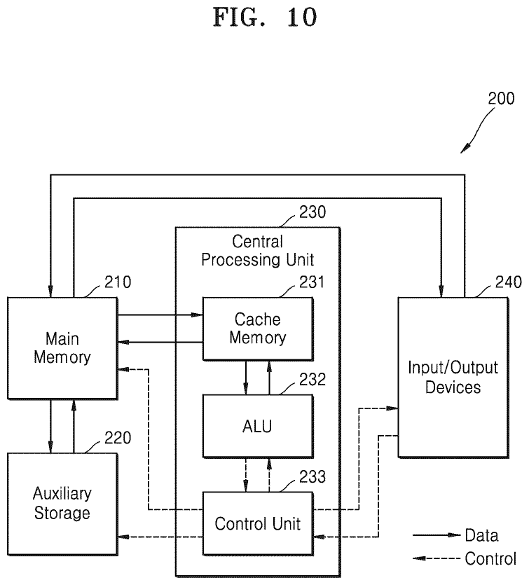

The memory device 100 described above may be used to store data in various electronic devices. FIG. 10 is a conceptual diagram schematically illustrating a device architecture applicable to electronic devices according to embodiments. Referring to FIG. 10, an electronic device 200 may include a main memory 210, an auxiliary storage 220, a central processing unit (CPU) 230, and an input/output devices 240. The CPU 230 may include a cache memory 231, an arithmetic logic unit (ALU) 232, and a control unit 233. The cache memory 231 may include a static random access memory (SRAM). The main memory 210 may include a DRAM, and the auxiliary storage 220 may include the memory device 100 according to an embodiment. Alternatively, all of the cache memory 231, the main memory 210, and the auxiliary storage 220 may include the memory device 100 according to the embodiment. In some cases, the electronic device 200 may be implemented in a single chip in which computing unit devices and memory unit devices are adjacent to each other, without distinction between the sub-units described above.

While the memory device including the above-described Ovonic threshold switching material is described above with reference to the embodiments shown in the drawings, it will be understood by one of ordinary skill in the art that various changes in form and details may be made therein. The disclosed embodiments should be considered in descriptive sense only and not for purposes of limitation. Therefore, the scope of the disclosure is defined not by the detailed description of the invention but by the appended claims, and all differences within the scope will be construed as being included in the present invention.

Hereinafter, the method of forming the chalcogenide-based thin film by atomic layer deposition according to the embodiment will be described in more detail with reference to the following examples.

### EXAMPLES

### Precursor Materials and Atomic Layer Deposition (ALD) Chamber

Bis[bis(trimethylsilyl)amino]germanium (Ge(N(Me₃Si)₂)₂) (purchased from: Humist Co., Ltd.) was used as a Ge precursor.

Bis(trimethylsilyl) selenide (Se(Me₃Si)₂) (purchased from: Humist Co., Ltd.) was used as a Se precursor.

Antimony ethoxide (Sb(OEt)₃) (purchased from: Strem Chemicals) was used as a Sb precursor.

Methanol was purchased from Strem Chemicals and used.

A self-made ALD chamber was used for atomic layer deposition.

### Example 1: Formation of Sb—Se Thin Film

A Si substrate with 300 nm of SiO₂ deposited was placed in the ALD chamber and Sb(OEt)₃ was injected thereinto at a flow rate of 50 sccm for 5 seconds while maintaining a chamber pressure of 3 Torr, and then the chamber was purged with Ar gas for 20 seconds. Subsequently, Se(Me₃Si)₂ and methanol were injected thereinto at flow rates of 50 sccm and 10 sccm, respectively, for 3 seconds while maintaining a chamber pressure of 3 Torr, and then the chamber was purged with Ar gas for 15 seconds. This process constituted one ALD cycle, and the chamber temperature was maintained at 70° C. during the cycle. The cycle was repeated to form a Sb—Se thin film.

### Comparative Example 1: Formation of Sb—Se Thin Film

A Si substrate was placed in the ALD chamber and Sb(OEt)₃ was injected at a flow rate of 50 sccm for 3 seconds while maintaining a chamber pressure of 3 Torr, and then the chamber was purged with Ar gas for 10 seconds. Subsequently, Se(Me₃Si)₂ was injected thereinto at a flow rate of 50 sccm for 3 seconds while maintaining a chamber pressure of 3 Torr, and then the chamber was purged with Ar gas for 15 seconds. This process constituted one ALD cycle, and the chamber temperature was maintained at 70° C. during the cycle. The cycle was repeated to form a Sb—Se thin film.

### Evaluation of Sb—Se Thin Film

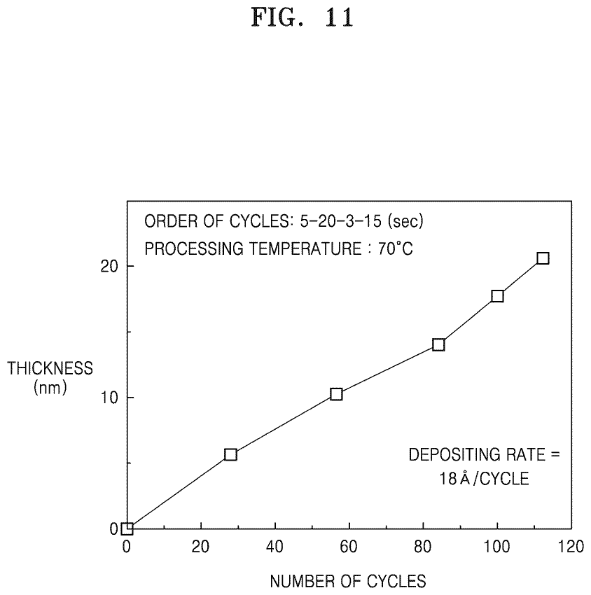

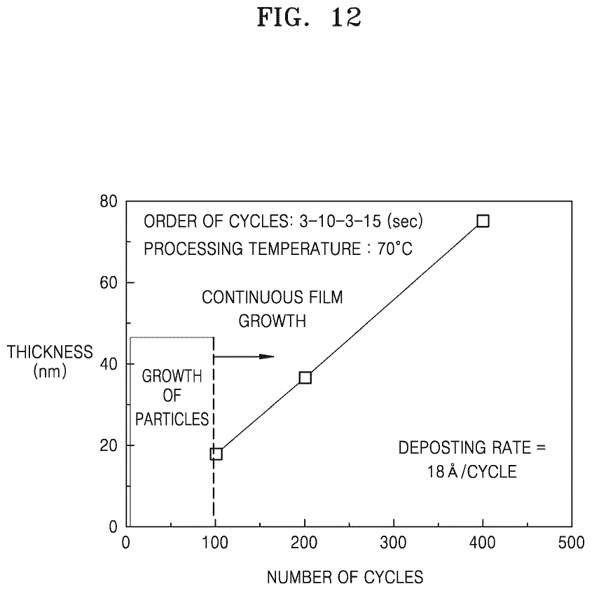

FIGS. 11 and 12 are graphs showing thicknesses of the Sb—Se thin films formed according to Example 1 and Comparative Example 1, respectively, with respect to the number of ALD cycles. Referring to FIG. 11, the thickness of the Sb—Se thin film formed in Example 1 could be measured from about 5 Å and linearly increases in proportion to the number of cycles. In this regard, a deposition thickness per one cycle was about 1.8 Å. Referring to FIG. 12, the thickness of the Sb—Se thin film formed in Comparative Example 1 could be measured from about 100 Å and linearly increases in proportion to the number of cycles. In Comparative Example 1, the deposition thickness per cycle was approximately 1.8 Å similar to that of Example 1. However, the thickness of the Sb—Se thin film of Comparative Example 1 was not reliably measured when less than 100 Å. This is because the thin film is considered to grow discontinuously at a thickness less than 100. On the contrary, it may be confirmed that the Sb—Se thin film of Example 1 uniformly and continuously grow even at a thickness of about 5 Å.

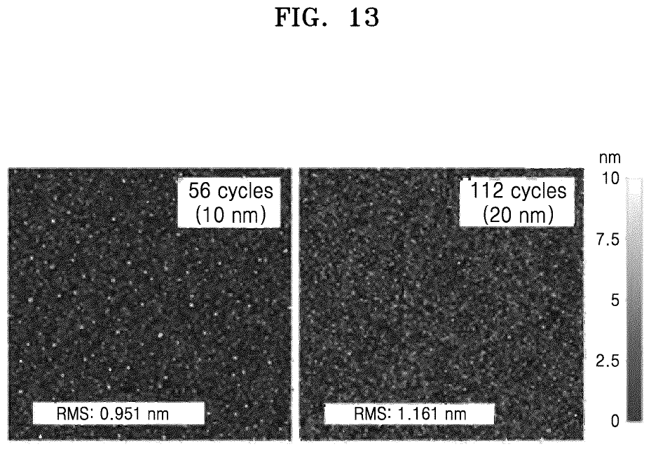

FIG. 13 shows AFM images of the Sb—Se thin films formed by performing ALD cycles 56 times and 112 times, respectively according to the method of Example 1. Referring to FIG. 13, the 10 nm-thick Sb—Se thin film formed by 56 cycles and the 20 nm-thick Sb—Se thin film formed by 112 cycles had RMS values of 0.95 nm and 1.2 nm, respectively, indicating similar values.

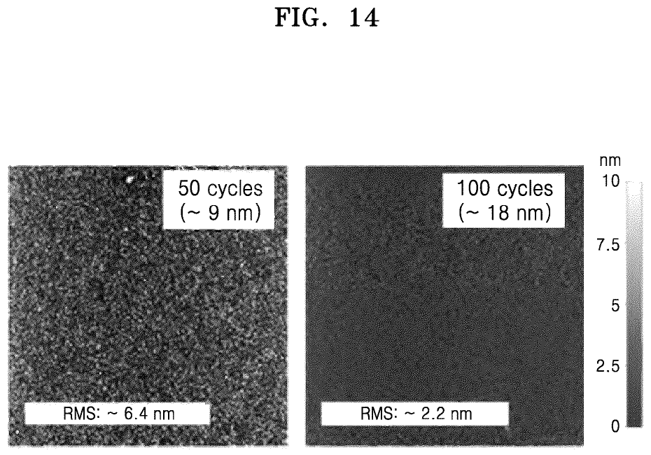

FIG. 14 shows AFM images of the Sb—Se thin films formed by performing ALD cycles 50 times and 100 times, respectively according to the method of Comparative Example 1. Referring to FIG. 14, a surface roughness of the 9 nm-thick Sb—Se thin film formed by 50 cycles had an RMS of about 6.4 nm which is about 3 times greater than an RMS of about 2.2 nm of the 18 nm-thick Sb—Se thin film formed by 100 cycles. That is, the Sb—Se thin film of Comparative Example 1 had a greater surface roughness as the thickness of the Sb—Se thin film decreases.

In addition, the 10 nm-thick Sb—Se thin film of Example 1 had a surface roughness about 6 times smaller than that of the 9 nm-thick Sb—Se thin film of Comparative Example 1, and the 20 nm-thick Sb—Se thin film of Example 1 had a surface roughness of about twice smaller than the 18 nm-thick Sb—Se thin film of Comparative Example 1.

Therefore, the Sb—Se thin film formed according to Example 1 had superior surface roughness property to the Sb—Se thin film prepared according to Comparative Example 1 in the case of both thicknesses of 10 nm and 20 nm.

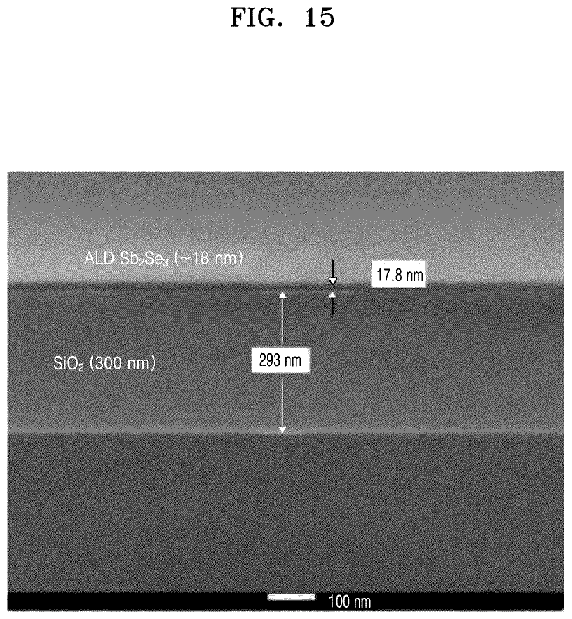

FIG. 15 is a cross-sectional SEM image of a Sb—Se thin film formed according to a method of Example 1. In the SEM image of FIG. 5, a Sb—Se thin film with a thickness of about 18 nm was uniformly formed on the SiO₂ layer with a thickness of about 300 nm.

### Example 2: Formation of Ge—Sb—Se Thin Film

### Ge—Se Cycle

A Si substrate with 300 nm of SiO₂ deposited was placed in the ALD chamber and Ge(N(Me₃Si)₂)₂ and methanol were injected thereinto at flow rates of 50 sccm and 10 sccm, respectively, for 5 seconds while maintaining a chamber pressure of 3 Torr, and then the chamber was purged with Ar gas for 10 seconds. Subsequently, Se(Me₃Si)₂ and methanol were injected thereinto at flow rates of 50 sccm and 10 sccm, respectively, for 3 seconds while maintaining a chamber pressure of 3 Torr, and then the chamber was purged with Ar gas for 15 seconds. This process constituted one Ge—Se subcycle. During the Ge—Se cycle, the chamber temperature was maintained at 70° C.

### Sb—Se Cycle

After the Ge—Se cycle, Sb(OEt)₃ was injected into the ALD chamber at a flow rate of 50 sccm for 5 seconds while maintaining a chamber pressure of 3 Torr, and the chamber was purged with Ar gas for 10 seconds. Subsequently, Se(Me₃Si)₂ and methanol were injected thereinto at flow rates of 50 sccm and 10 sccm, respectively, for 3 seconds while maintaining a chamber pressure of 3 Torr, and then the chamber was purged with Ar gas for 10 seconds. The process constituted one Sb—Se subcycle. During the Sb—Se subcycle, the chamber temperature was maintained at 70° C.

One Ge—Se cycle is combined with one Sb—Se cycle to form a super cycle. The number of the Ge—Se subcycle in the Ge—Se cycle was 1, and the number of Sb—Se subcycle in the Sb—Se cycle was 1. Therefore, a ratio of the number of the Ge—Se subcycle to the number of the Sb—Se subcycle was 1:1.

### Example 3: Formation of Ge—Sb—Se Thin Film

A Ge—Sb—Se thin film was formed in the same manner as in Example 2, except that the number of the Ge—Se subcycle constituting the Ge—Se cycle was 1, and the number of the Sb—Se subcycle constituting the Sb—Se cycle was 2. Therefore, a ratio of the number of the Ge—Se subcycle to the number of the Sb—Se subcycle was 1:2.

### Example 4: Formation of Ge—Sb—Se Thin Film

A Ge—Sb—Se thin film was formed in the same manner as in Example 2, except that the number of the Ge—Se subcycle constituting the Ge—Se cycle was 1, and the number of the Sb—Se subcycle constituting the Sb—Se cycle was 3. Therefore, a ratio of the number of the Ge—Se subcycle to the number of the Sb—Se subcycle was 1:3.

### Measurement of Composition Ratio in Thin Film

Composition ratios (at %) of Ge, Sb and Se in the Ge—Sb—Se thin films formed in Examples 2 to 4 were measured by using an ICP device (5900, Agilent).

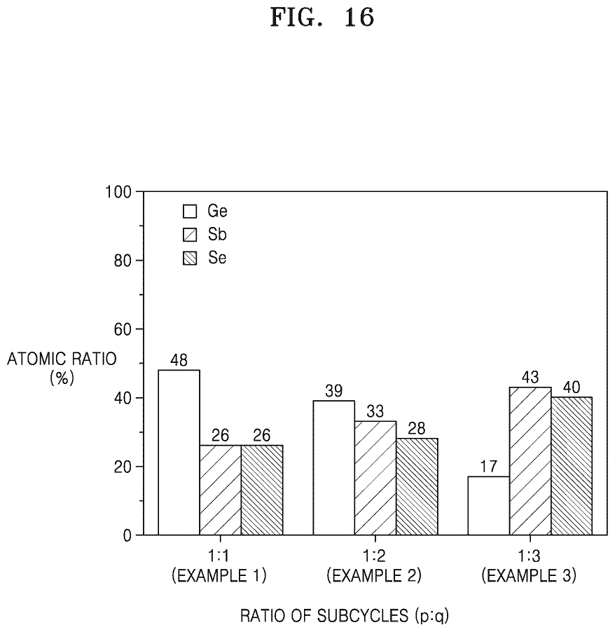

The ratios of the number of subcycles (p) in the Ge—Se cycle and the number of subcycles (q) in the Sb—Se cycle, and the atomic ratio % of Ge, Sb and Se in the formed Ge—Sb—Se thin films of Examples 2 to 4 are shown in Table 1 below and FIG. 16.

TABLE 1

| | | Ge | Sb | Se |
|---|---|---|---|---|
| | p:q | (at %) | (at %) | (at %) |
| Example 2 | 1:1 | 48 | 26 | 26 |
| Example 3 | 1:2 | 39 | 33 | 28 |
| Example 4 | 1:3 | 17 | 43 | 40 |

Referring to Table 1 and FIG. 16, as the number of the Sb—Se subcycles increases compared to the number of the Ge—Se subcycles in the formation of the Ge—Sb—Se thin film, the atomic ratio % of Sb increases and the atomic ratio % of Ge decreases in the thin films. Therefore, by adjusting the number (p) of the Ge—Se subcycles in the Ge—Se cycle and the number (q) of the Sb—Se subcycles in the Sb—Se cycle, the composition ratio of Ge, Sb and Se in the Ge—Sb—Se thin film may be adjusted.

### Example 5: Preparation of Vertical Structure Deposited with Ge—Sb—Se Thin Film

A 20 nm-thick SiO₂ layer and a 10 nm-thick TiN layer were alternately formed on a Si substrate to form a 2.1 μm-thick stack structure. Through-holes with a diameter of 50 nm were formed to penetrate the stack structure. Due to a diameter of 50 nm and a depth of 2,100 nm, the through-hole has an aspect ratio of 42:1. A 20 nm-thick Ge—Sb—Se thin film was formed in the through-hole according to the method described in Example 3.

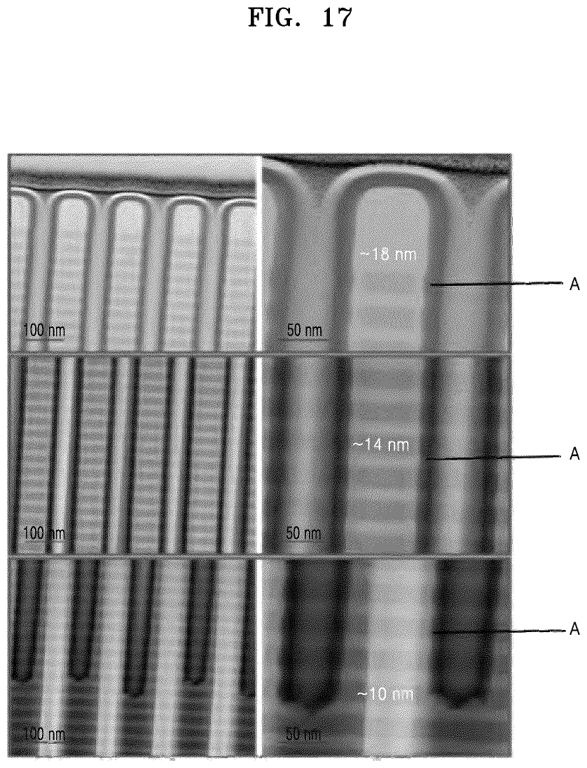

FIG. 17 shows cross-sectional TEM images of the structure of Example 5. For TEM analysis, a carbon layer was filled in the through-holes formed with the Ge—Sb—Se thin film, and a Ge—Sb—Se thin film (A) is shown between the stack structure and the carbon layer.

The upper row of FIG. 17 shows upper areas of the through-holes, the middle row shows middle areas of the through-holes, and the lower row shows lower areas of the through-holes. Right images of FIG. 17 are enlarged images of left images of each row. In FIG. 17, a portion where the Ge—Sb—Se thin film is deposited is indicated by A. Referring to FIG. 17, the portion A where the Ge—Sb—Se thin film is formed is clearly shown between the side of the through-hole and the carbon layer filled in the through-hole. The portion A where the Ge—Sb—Se thin film is formed had a uniform thickness in all of the upper area, the middle area, and the lower area of the through-hole. As a result, it may be confirmed that the Ge—Sb—Se thin film is uniformly formed in the structure of Example 5 in the through-hole having a diameter of 50 nm and an aspect ratio of 42:1.

By using the alcohol (e.g., C₁-C₄ alcohol and the like) as the co-reactant in the formation of the Ge—Sb—Se-containing chalcogenide-based thin film by atomic layer deposition, a thin film having a more uniform composition and an improved step coverage property may be provided. By using the method of forming a chalcogenide-based thin film, the chalcogenide-based thin film may be uniformly formed in the through-hole of a memory device with a higher aspect ratio, thereby providing a more reliable memory device.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of forming a chalcogenide-based thin film by atomic layer deposition, the method comprising:
a first cycle of forming a Ge—Se layer on a substrate, the first cycle including supplying a Ge precursor, a Se precursor, and a C₁-C₄ alcohol as co-reactants into a reaction chamber while the substrate is in the reaction chamber; and
a second cycle of forming a Sb—Se layer on the substrate, the second cycle including supplying a Sb precursor, the Se precursor, and a C₁-C₃ alcohol as co-reactants into the reaction chamber while the substrate is in the reaction chamber, wherein
the Ge precursor comprises an amine ligand,
the Se precursor comprises an alkylsilyl group,
the Sb precursor comprises an alkoxide group,
the first cycle comprises p first subcycles,
the second cycle comprises q second subcycles,
among the p first subcycles and the q second subcycles, p and q are each independently selected from integers of 1 to 10, and
the first cycle and the second cycle are alternately performed multiple times.

2. The method of claim 1, wherein each of the p first subcycles comprises:
a first process of supplying the Ge precursor and the C₁-C₄ alcohol to the reaction chamber;
a second process of purging the reaction chamber;
a third process of supplying the Se precursor and the C₁-C₄ alcohol to the reaction chamber; and
a fourth process of purging the reaction chamber.

3. The method of claim 1, wherein each of the q second subcycles comprises:
a first process of supplying the Sb precursor to the reaction chamber;
a second process of purging the reaction chamber;
a third process of supplying the Se precursor and the C₁-C₃ alcohol to the reaction chamber; and
a fourth process of purging the reaction chamber.

4. The method of claim 1, wherein the chalcogenide-based thin film is a Ge—Sb—Se thin film.

5. The method of claim 1, wherein
the chalcogenide-based thin film is a Ge—Sb—Se thin film, and
a composition ratio of Ge, Sb and Se contained in the Ge—Sb—Se thin film formed from performing the first cycle and the second cycle multiple times is adjusted by controlling a ratio of p to q for the p first subcycles and the q second subcycles.

6. The method of claim 1, wherein the chalcogenide-based thin film comprises 10 at % to 40 at % of germanium (Ge), 10 at % to 40 at % of antimony (Sb), and 30 at % to 60 at % of selenium (Se).

7. The method of claim 1, wherein the chalcogenide-based thin film has a surface roughness of 1.5 nm (RMS) or less.

8. The method of claim 1, wherein the chalcogenide-based thin film is an Ovonic threshold switching material.

9. A method of forming a chalcogenide-based thin film by atomic layer deposition, the method comprising:
repeating a cycle of forming a Sb—Se layer on a substrate by supplying a Sb precursor, a Se precursor, and a C₁-C₃ alcohol as a co-reactant to a reaction chamber while the substrate is in the reaction chamber, wherein
the Sb precursor comprises an alkoxide group, and
the Se precursor comprises an alkylsilyl group.

10. The method of claim 9, wherein the cycle comprises:
a first process of supplying the Sb precursor to the reaction chamber;
a second process of purging the reaction chamber;
a third process of supplying the Se precursor and the C₁-C₃ alcohol to the reaction chamber; and
a fourth process of purging the reaction chamber.

11. The method of claim 9, wherein the chalcogenide-based thin film is a Sb—Se thin film.

12. The method of claim 9, wherein the C₁-C₃ alcohol comprises methanol.

13. The method of claim 9, wherein the Se precursor comprises bis(trimethylsilyl)selenide.

14. A method of fabricating a memory device, the method comprising:
forming a stack structure including conductive layers and insulating layers alternately stacked on a substrate;
forming a through-hole in the stack structure, the through-hole vertically extending through the stack structure;
forming a chalcogenide layer on a side wall of the through-hole; and
filling the through-hole with a conductive material after the forming the chalcogenide layer on the side wall of the through-hole,
wherein the forming the chalcogenide layer on the side wall of the through-hole comprises
inserting the substrate having the through-hole, the through-hole being defined by the stack structure on the substrate, into a reaction chamber,
a first cycle of forming a Ge—Se layer on the side wall of the through-hole by supplying a Ge precursor, a Se precursor, and a C₁-C₄ alcohol to the reaction chamber; and
a second cycle of forming a Sb—Se layer on the side wall of the through-hole by supplying a Sb precursor, the Se precursor, and a C₁-C₃ alcohol to the reaction chamber,
wherein
the Ge precursor comprises an alkylamine group,
the Se precursor comprises an alkylsilyl group,
the Sb precursor comprises an alkoxide group,
the first cycle comprises p first subcycles,
the second cycle comprises q second subcycles,
among the p first subcycles and the q second subcycles, p and q are each independently selected from integers of 1 to 10, and
the first cycle and the second cycle are alternately performed multiple times.

15. The method of claim 14,
wherein each of the p first subcycles comprises
a first process of supplying the Ge precursor and the C₁-C₄ alcohol to the reaction chamber,
a second process of purging the reaction chamber,
a third process of supplying the Se precursor and the C₁-C₄ alcohol to the reaction chamber, and
a fourth process of purging the reaction chamber, and
each of the q second subcycles comprises
a first operation of supplying the Sb precursor to the reaction chamber,
a second operation of purging the reaction chamber,
a third operation of supplying the Se precursor and the C₁-C₃ alcohol to the reaction chamber, and
a fourth operation of purging the reaction chamber.

16. The method of claim 14, wherein the chalcogenide layer is a Ge—Sb—Se layer.

17. The method of claim 14, wherein
the chalcogenide layer is a Ge—Sb—Se thin film, and
a composition ratio of Ge, Sb and Se contained in the Ge—Sb—Se thin film is adjusted by controlling a ratio of p to q for the p first subcycles and the q second subcycles.

18. The method of claim 14, wherein the chalcogenide layer comprises 10 at % to 40 at % of germanium (Ge), 10 at % to 40 at % of antimony (Sb), and 30 at % to 60 at % of selenium (Se).

19. The method of claim 14, wherein
each of the conductive layers is a word plane,
the chalcogenide layer is a selective storage layer, and
the conductive material in the through-hole is a vertical bit line.

20. The method of claim 19, wherein the substrate further comprises a transistor connected to the vertical bit line.
